(19) United States
(12) Patent Application Publication
(10) Pub. No.: US 2026/0278463 A1
(43) Pub. Date: Sep. 17, 2026

(54) A METHOD TO MONITOR THE CGI MODEL PERFORMANCE WITHOUT GROUND TRUTH INFORMATION

(71) Applicant: ASML Netherlands B.V., Veldhoven (NL)

(72) Inventors: Chenxi LIN, Newark, CA (US); Fuming WANG, Santa Clara, CA (US)

(73) Assignee: ASML Netherlands B.V., Veldhoven (NL)

(21) Appl. No.: 19/469,648

(22) PCT Filed: Mar. 1, 2024
(86) PCT No.: PCT/EP2024/055300

§ 371 Date: Sep. 26, 2025

Related U.S. Application Data
(60) Provisional application No. 63/455,505, filed on Mar. 29, 2023.

(51) Int. Cl. G06N 20/00

(52) U.S. Cl. CPC G06N 20/00

(57) ABSTRACT

An apparatus to perform a method for detecting a change in computational model behavior is disclosed. The method comprises monitoring a contribution of a selected sample feature to a defective die probability evaluation over a time interval, determining whether the contribution of the selected sample feature exceeds a drift threshold in the time interval, and based on the determination that the drift threshold is exceeded, retraining the computational model.

### CROSS-REFERENCE TO RELATED APPLICATION

This application claims priority of U.S. application 63/455,505 which was filed on 29 Mar. 2023, and which is incorporated herein in its entirety by reference.

### TECHNICAL FIELD

The embodiments provided herein relate to computational guided inspection, and more particularly to a method to monitor a change in performance of a computational guided inspection model used to generate a defective die probability estimate without relying on ground truth information.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Various metrology tools are developed and used to check whether the ICs are correctly manufactured. To improve defect inspection performance, a computational guided inspection (CGI) machine learning model may be used to assist the tools by indicating areas of a wafer to be inspected.

### SUMMARY

The embodiments provided herein disclose a method to detect a change in computational model behavior, and more particularly, a method of using a computational model to inspect a wafer.

Some embodiments provide an apparatus for detecting a change in computational model behavior comprising a memory storing a set of instructions and at least one processor configured to execute the set of instructions to cause the apparatus to perform a method for detecting a change in computational model behavior. The method comprises monitoring a contribution of a selected sample feature to a defective die probability evaluation over a time interval, determining whether the contribution of the selected sample feature exceeds a drift threshold in the time interval, and based on the determination that the drift threshold is exceeded, retraining the computational model.

Other advantages of the present invention will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged-particle beam inspection system, consistent with embodiments of the present disclosure.

FIG. 2 is a schematic diagram illustrating an example multi-beam tool that can be a part of the example charged-particle beam inspection system of FIG. 1, consistent with embodiments of the present disclosure.

FIG. 3 is a schematic block diagram illustrating throughput to generate input data, consistent with embodiments of the present disclosure.

FIG. 4 is an example conventional method to estimate defective die probability using the CGI model and monitoring the CGI model accuracy with “ground truth” result comparison.

FIG. 5 is an example method to estimate defective die probability using the CGI model and monitoring the CGI model accuracy over time without “ground truth” result comparison, consistent with embodiments of the present disclosure.

FIGS. 6A and 6B are example plots illustrating monitoring a change in a contribution of a selected sample feature to an estimated defective die probability over time, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged-particle beams (e.g., including protons, ions, muons, or any other particle carrying electric charges) may be similarly applied. Furthermore, other imaging systems may be used, such as optical imaging, photon detection, x-ray detection, ion detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. The enhanced computing power of electronic devices, while reducing the physical size of the devices, can be accomplished by significantly increasing the packing density of circuit components such as transistors, capacitors, diodes, etc. on an IC chip. For example, an IC chip of a smart phone, which is the size of a thumbnail, may include over 2 billion transistors, the size of each transistor being less than 1/1000th of a human hair.

ICs may be manufactured using lithography, which is a fabrication process involving creating complex circuit patterns drawn on a mask deposited onto a substrate. Lithography may be performed by a lithographic apparatus, which is a machine that applies a source of radiation (e.g., light or X-ray) onto a target portion of the substrate to form a desired pattern. The target portion of the substrate may be covered with a pattern device (e.g., mask) that may be either eliminated or developed after exposure to the radiation source. This process of transferring the desired pattern to the substrate is called a patterning process. The patterning process may include a patterning step to transfer a pattern from a pattern device (e.g., a mask) to the substrate. There can also be one or more related pattern processing steps, such as mask development by a development apparatus, baking of the substrate using a bake tool, etching the pattern onto the substrate using an etch apparatus, or other chemical and physical processing steps involved in fabricating a pattern onto the substrate. Variations in experimental parameters (e.g., stochastic variations, errors, or noise due to an inspection tool or pattern processing tool) can potentially limit lithography implementation for high volume manufacturing (HVM), or process yield, of ICs and introduce defects into IC structures.

In the manufacture of ICs using a lithographic apparatus, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers. For this purpose, the substrate is provided with one or more sets of alignment marks. Each mark is a structure having a position that can be measured later using, for example, an electron beam inspection tool. Defects may occur in which an applied pattern structure or pattern layer is incorrectly placed in relation to a reference mark, or when the fabrication conditions are suboptimal. A reference mark or layout define the desired structure, structure dimensions, and the distance between IC structures (such as gates, capacitors, etc.) or interconnect lines. This may ensure that the IC devices or lines do not interact with one another in an undesirable way. The structure limitations provided by the reference layouts are typically referred to as critical dimensions. A critical dimension of a circuit can be defined as the smallest width of a line or hole or the smallest space between two lines or two holes. Thus, the critical dimension determines the overall size and packing density of the designed IC. A goal in IC fabrication is to faithfully reproduce the original IC design on the substrate. If an error occurs during fabrication where the created IC design pattern does not match the reference design, this may result in a defect in the IC structure and render the IC inoperable.

Making these ICs with extremely small structures or components is a complex, time-consuming, and expensive process, often involving hundreds of individual steps. Errors in even one step have the potential to dramatically affect the function of the final product. Even one “killer defect” can cause device failure. The goal of the manufacturing process is to improve the overall yield of the process. For example, for a 50-step process to get to a 75% yield, each individual step must have a yield greater than 99.4%, and if the individual step yield is 95%, the overall process yield drops to 7%.

While high process yield is desirable in an IC chip manufacturing facility, maintaining a high wafer throughput, defined as the number of wafers processed per hour, is also essential. High process yields and high wafer throughput can be impacted by the presence of defects, especially if operator intervention is required for reviewing the defects. Thus, high throughput detection and identification of micro and nano-sized defects is desired. One component of improving process yield and wafer throughput may be monitoring the IC fabrication process to ensure a desired number of defect-free ICs are produced. One way to monitor the fabrication process is to inspect the chip circuit structures at various stages of fabrication. Inspection using tools such as, for example, a charged particle beam inspection tool may be used to this effect to maintain high process yield and high wafer throughput. Inspection of a wafer using an electron beam inspection tool may generate images of the wafer to measure IC structure dimensions. The measured dimensions may be compared to a reference structure absent any defects to determine the presence of defects in the imaged structure. If the structure is defective, then the fabrication process can be adjusted, so the defect is less likely to recur. However, inspection of ICs for defect detection is often a time-consuming process and may not definitively identify the presence of defects on a wafer. It is desired to identify any defects that occur during the fabrication stages instead of further refining IC inspection methods.

Current computational guided inspection (CGI) processes may monitor IC fabrication processing steps to identify possible defect formation and guide inspection tools to locations on a wafer where there is a higher probability of defects. A machine learning-based CGI model receives input from various data sources, such as wafer characteristic data (which may include scanner data, metrology data, and fabrication process data) to train the model with inspection results. A CGI machine learning model may be built and used to output a sampling plan indicating a location on a wafer where defects have likely formed after a fabrication processing step, so the inspection tool will go to the sampling location to inspect with a higher efficiency than inspecting wafer locations based on experience (e.g., a history of prior defects detected during scanning). The CGI process occurs in-line with wafer fabrication and increases inspection tool efficiency by increasing the accuracy of finding defects on the wafer with capture rates of finding defects higher than a baseline value. The inspection results may be used to confirm a satisfactory wafer yield is maintained throughout manufacturing and to project the failure rate, or die loss per wafer, at the end of production. This projected failure rate may be compared to the results of a wafer probe test, which determines a failure rate for each die fabricated on the wafer. A final metric of a CGI model use case may be the correlation R2 value between the estimated and measured die defects for a wafer. A final metric may also be the capture rate of instances where the CGI sampling plan captures defective dies at certain locations on a wafer (also known as the “fingerprint”) that have historically low defect probability. This fingerprint may be referred to as an excursion fingerprint or excursion event.

The prediction accuracy of a CGI model might degrade over time. This phenomenon may be referred to as “concept drift.” If a model excursion event occurs, it is desirable to identify this model inaccuracy before extensive wafer manufacturing occurs. If a degradation in the performance (e.g., accuracy in defective die location) of the CGI-estimated defective die probability is detected, the model may be re-trained to correct the accuracy of the model and maintain a desirable R² score for die loss projection and sampling plan accuracy.

In conventional systems, a method to monitor CGI model performance for a model inaccuracy (e.g., a model excursion) for a wafer inspected during high volume manufacturing (HVM) may be to compare CGI model prediction results (e.g., defective die or failure probability) to the “ground truth” results. The “ground truth” results may be inspection results via a charged particle beam inspection tool (e.g., scanning electron microscope, SEM) based on the CGI-provided sampling plan, or probe test results of a fully completed wafer at the end of production. Inspection results via an inspection tool may provide identification of defects at a specific location on a wafer. Probe test results provide accurate identification of defects for each die on a wafer. Using an inspection tool such as, for example, a SEM, as a “ground truth” result may inspect only a relatively small fraction of dies per wafer. This may limit the number of available data points for a timely CGI model excursion detection. Moreover, if the CGI model is inaccurate and generates a sampling plan not representative of a location containing defects on a wafer, inspection results may miss actual defects formed on a wafer. The defects may not be identified until probe test results are obtained. However, relying on probe test “ground truth” results to monitor and detect a CGI model excursion may cause further time delays since the probe test results may not be obtained until the wafer is completely processed, which could take months. In both instances, if a CGI model inaccurately predicts defects during wafer HVM, the model excursion may not be identified until after a significant number of defective wafers are manufactured.

Embodiments of the present disclosure may provide a method to monitor and detect changes in CGI model performance in estimating defective die probability of a wafer without relying on a “ground truth” value. Some embodiments of the present disclosure may provide a method for monitoring a change in a computational model behavior over time to determine if a contribution of a selected sample feature to an estimated defective die probability exceeds a drift threshold. Some embodiments of the present disclosure may also provide a method to reduce the time to detect a change in the computational model behavior. Some embodiments of the present disclosure may provide a method to detect a CGI model excursion event before a “ground truth” result is obtained. Some embodiments of the present disclosure may provide a method to increase the CGI model accuracy and yield of defect-free wafers throughout HVM.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

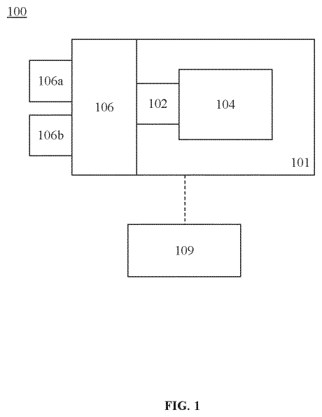

FIG. 1 illustrates an example electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for wafer processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controller, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

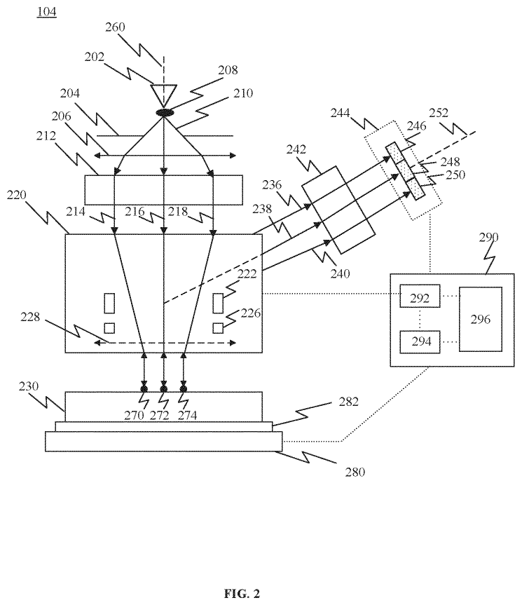

FIG. 2 illustrates a schematic diagram of an example multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218.

While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, the apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SCPM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SCPM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

Although reference may be made in the present disclosure to ICs, it is appreciated that the present disclosure may be applicable to other possible applications or designs. For example, the present disclosure may be applied to integrated optical systems, magnetic domain memories, liquid-crystal display panels, thin-film magnetic heads, and other nanoscale structures. It is further appreciated that the terms “die”, “structure”, and “IC structure” are used interchangeably in this disclosure.

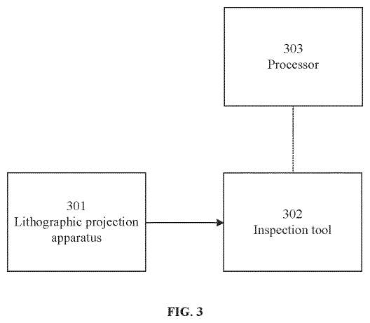

Reference is now made to FIG. 3, which is an example block diagram for generating input data, consistent with embodiments of the present disclosure. Input data may be generated using two steps as illustrated in FIG. 3. A lithographic projection apparatus 301 may be used to fabricate a wafer at a constant fabrication condition (e.g., a focus and dose for a radiation source). An inspection tool 302 (e.g., EBI system 100 in FIG. 1 or multi-beam tool 104 in FIG. 2) may be used to measure metrology information of structures formed on the wafer that was generated by lithographic projection apparatus 301. Metrology information may include, but is not limited to, necking, line pull back, line thinning, critical dimension, edge placement, overlapping, resist top loss, resist undercut, missing defects, and bridging defects of an IC structure on a wafer. A processor 303 (e.g., controller 109 in FIG. 1) with a memory may be communicatively connected to inspection tool 302 to store the measured metrology information. In some embodiments, processor 303 is part of inspection tool 302.

The images generated by inspection tool 302 may be used for wafer inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, inspection tool 302 may scan multiple regions of the wafer, each region including a test device region designed as the same and generate multiple images capturing those test device regions as manufactured. The multiple images may be compared with each other. If a difference between the multiple images exceeds a tolerance level, a potential defect may be identified.

In some embodiments, processor 303 may be a generic or specific electronic device capable of manipulating or processing information. For example, processor 303 may include any combination of any number of a central processing unit (or “CPU”), a graphics processing unit (or “GPU”), an optical processor, a programmable logic controller, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. Processor 303 may also be a virtual processor that includes one or more processors distributed across multiple machines or devices coupled via a network.

In some embodiments, processor 303 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

Conventional computational guided inspection (CGI) processes guide inspection tools to locations on a wafer where there is a higher probability of defects. As described above, a machine learning-based CGI model receives input from various data sources, including wafer characteristic data such as scanner data, metrology data, and fabrication process data to train the model with inspection results. A CGI machine learning model may be built and used to output a sampling location on the wafer, so the inspection tool will go to the sampling location to inspect with a higher efficiency than inspecting wafer locations based on experience (e.g., a history of prior defects in a given location detected during scanning). Thus, the CGI model may use input data from a reference wafer (e.g., a reference pattern, metrology information, etc., according to a fabrication or wafer processing step) to thus guide future inspection of wafers processed during HVM. The CGI model increases inspection tool efficiency by increasing the accuracy of finding defects on the wafer with capture rates of finding defects higher than a baseline value. However, a deviation of the CGI model behavior or performance over time (e.g., applying the CGI model to subsequent wafers) may result in defective wafers processed during HVM that will not be identified until the end of processing once the “ground truth” results are obtained. This would therefore lead to a large number of inoperable wafers that may not be identified until post-processing and therefore decrease processing yield.

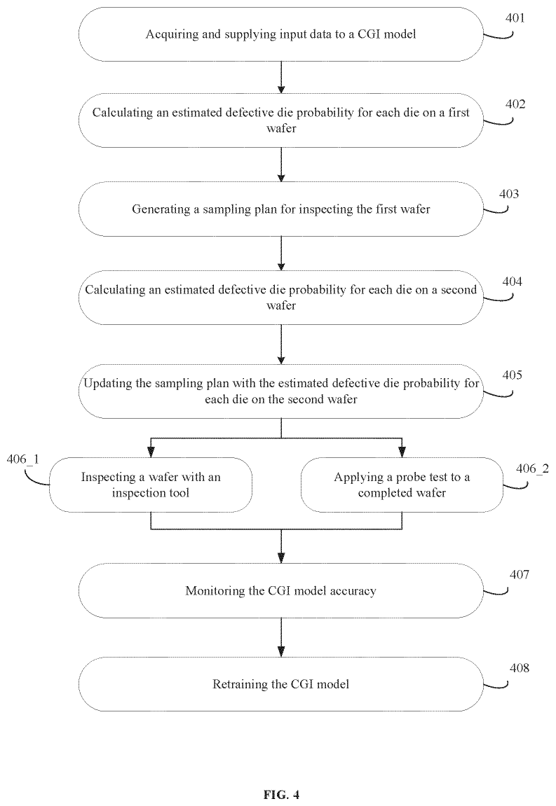

Reference is now made to FIG. 4, which is an example flow diagram of a conventional CGI method to estimate defective die probability according to wafer processing and monitoring the CGI method accuracy with “ground truth” result comparison. The steps of FIG. 4 may be performed by a computing device. In step 401, input data is acquired and supplied to a CGI model. The input data may correspond to metrology information collected from a first wafer and a second wafer that are acquired via wafer processing during HVM. The wafer processing may be a lithographic focus and dose condition from a focus-exposure matrix. The metrology information may include, but is not limited to, necking, line pull back, line thinning, critical dimension, edge placement, overlapping, resist top loss, resist undercut, missing defects, and bridging defects on a wafer.

In step 402, the CGI model is applied to the first wafer to calculate an estimated defective die probability for each die on the first wafer that is acquired via wafer processing. The calculation may be based on identified defects in the input data for the first wafer and is influenced by the input data quality. In step 403, a sampling plan for in-line wafer inspection via an inspection tool (e.g., a SEM) is generated using the estimated defective die probability on the first wafer. The CGI-generated sampling plan serves to indicate a region of structures on the wafer that will accurately represent a completed wafer post-production. Certain fitting algorithms, such as Zernike or polynomial based fitting, can be applied to the input data and calculated defective die probability to create a sampling plan for wafer inspection in-line with HVM. In step 404, the CGI model is applied to a second wafer that is acquired via wafer processing to calculate an estimated defective die probability for each die on the second wafer. In step 405, the sampling plan generated by the CGI model in step 403 is updated to include the estimated defective die probability for each die on the second wafer. This is known as dynamic sampling and is explained more below. In-line inspection step 406_1 may occur after wafer processing to detect possible defects on a wafer according to the CGI-generated dynamic sampling plan.

In step 406_2, a probe test is applied to a completed wafer (e.g., a fully processed or fabricated wafer at the end of manufacturing) to generate probe test results. As discussed above, a wafer may take weeks to months to be completely fabricated. Therefore, weeks or months may pass between steps 405 and 406_2. The probe test analyzes every die or structure on the completed wafer and determines how many defects are present (e.g., determines the actual defective die result of the wafer). The probe test result is thus referred to as the “ground truth” result.

In step 407, the CGI model accuracy is monitored by comparing the inspection result or the probe test result to the estimated defective die probability generated by the CGI model and used for the sampling plan. If the probe test indicates a defect at a location on a wafer where no defect was predicted according to the sampling plan generated by the CGI model or the other way around, then this may mean the sampling plan generated by the CGI model is inaccurate and may need to be retrained. Furthermore, since the CGI model may be applied to monitor wafer yield throughput processing, there may be a greater chance that more defective wafers were manufactured than what was estimated. In step 408, after the ground truth results are obtained, the CGI model is retraining by repeating step 401, but with new input data and the ground truth results supplied to the CGI model.

The CGI model provides an output of a defective die probability at a die-to-die level. This means the CGI model estimates a defect probability for each die on a wafer, which may vary from die to die, and from wafer to wafer. The estimated defective die probability may be compiled to generate a dynamic sampling plan for a wafer. The dynamic sampling plan may be used to guide inspection of a wafer to extrapolate a projected die loss, which is a ratio of the defective dies estimated by the CGI model based on the predicted defective die probability and the inspection results to the total number of dies per wafer.

The CGI model creates dynamic sampling on the wafer, and the inspection tool inspects the locations based on the dynamic sampling on different wafers. The input data includes a large amount of metrology information on a wafer across dynamic locations. The input data output for a N+1 wafer, where N is an integer, is used to generate a defective die probability map that can be used to update the sampling plan generated by the CGI model. The N+1 wafer input data is thus used to update the defective die probability map generated from the N wafer. As each CGI inspection sampling is different from wafer to wafer, with accumulated input data, a defective die probability wafer map can be created at different defect aggregation levels, such as a die level, a care area, or an image patch level.

With hundreds of inspected regions across a wafer and the calculated defective die probability, certain fitting algorithms, such as Zernike or polynomial based fitting, can be used to extrapolate sparse metrology information, and thus sparse calculated defective die probabilities, to model every die on a given wafer. Thus, such fitting algorithms can be used to create a dynamic sampling plan for wafer inspection in-line with HVM. The dynamic defective die probability map may be derived from historical input data and combining new wafer characteristic data, such as scanner data, metrology data, and process data, on the next wafer to inspect. The defective die probability map is then used to update the sampling plan generated by the CGI model, and the updated sampling plan can predict a new inspection sampling for the next (N+1) wafer. After the N+1 wafer is inspected, its inspection results are provided to update the defective die probability map and to continue to improve the CGI model with the latest defective die probability map for the next wafer to be inspected.

To retrain the CGI model, inspection data output from the inspection tool or probe test results for a fully processed wafer are supplied to the CGI model. The inspection data from the inspection tool may be historical data or reference data (e.g., image of a reference wafer), or image data collected from a wafer acquired via wafer processing. The inspection data or the probe test results may be used to train the CGI model to generate a more accurate defective die probability map. However, as discussed above, in-line inspection of a wafer according to a sampling plan inspects only a fraction of the total dies or structures on a wafer.

Following conventional methods to monitor the accuracy of the CGI model over time using ground truth results may result in any CGI model inaccuracy, or excursion event of the CGI model, going unidentified until the end of wafer HVM when the ground truth results are obtained for a complete wafer. Despite the sampling plan generated by the CGI model being continuously updated to predict an estimated defective die probability for the next (N+1) wafer during HVM, conventional methods do not continuously monitor the CGI model for any deviations in accuracy. Thus, conventional methods may result in unknowingly fabricating a significant number of defective wafers during processing, resulting in serious negative consequences in wafer yield.

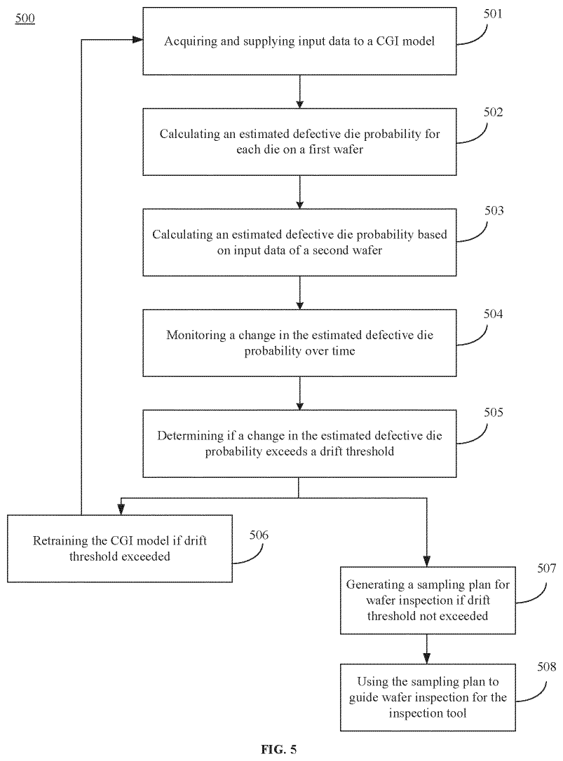

Reference is now made to FIG. 5, which is an example flow diagram of a method 500 to monitor a CGI model accuracy over time for a model excursion event without “ground truth” result comparison, consistent with embodiments of the present disclosure. The steps of method 500 may be performed by a computing device, e.g., processor 303 of FIG. 3. It is appreciated that the illustrated method 500 may be altered to modify the order of steps and to include additional steps.

In step 501, input data is acquired and supplied to a CGI model. The input data may correspond to metrology information collected from a first wafer and a second wafer that are acquired via wafer processing during HVM. The wafer processing may be a lithographic focus and dose condition. The metrology information may include, but is not limited to, necking, line pull back, line thinning, critical dimension, edge placement, overlapping, resist top loss, resist undercut, missing defects, and bridging defects on a wafer. In step 502, an estimated defective die probability for each die on the first wafer is calculated based on the input data for the first wafer. The calculation may be based on identified defects in the input data and is influenced by the input data quality. The calculation may be performed by a processor (e.g., processor 303 in FIG. 3) which may apply the CGI model to the first wafer.

In step 503, an estimated defective die probability for each die on the second wafer is calculated based on the input data for the second wafer. In some embodiments, the second wafer may be acquired via wafer processing after the first wafer. The calculation may be performed by a processor (e.g., processor 303 in FIG. 3) which may apply the CGI model to the second wafer. In some embodiments, the CGI model may be applied to the second wafer after the CGI model is applied to the first wafer.

In step 504, a change in the estimated defective die probability generated by the CGI model is monitored over time (e.g., CGI model application in steps 502 and 503). In some embodiments, a distribution of estimated defective die probabilities generated by the CGI model may be monitored to identify a change in the estimated defective die probability. The input data for the first wafer and the second wafer may contain a sample feature that has a high contribution or correlation to the estimated defective die probability calculated by the processor after each CGI model application. In some embodiments, a sample feature may be a metrology measurement as described above. In some embodiments, a sample feature may be a fabrication condition. As the input data for the first wafer and the second wafer may contain a plurality of sample features, embodiments of the present disclosure include identification techniques to separate the contribution or correlation of each sample feature to the estimated defective die probability calculated by the CGI model after each application. In some embodiments, the identification technique may include, but is not limited to, a sum of mean absolute Shapley Additive Explanations (SHAP) values, integrated gradients, local interpretable model-agnostic explanations (LIME), and other feature selection methods that do not rely on ground truth results. In some embodiments, the identification technique may be a sum of mean absolute SHAP values. In some embodiments, a SHAP value for a sample feature that contributes to the estimated defective die probability for the first wafer and the updated defective die probability for the second wafer is calculated and monitored over time to identify a potential change/degradation of the CGI model accuracy. In some embodiments, monitoring the CGI model may be initiated after a wafer processing step in wafer manufacturing.

In step 505, the CGI model is determined to be inaccurate if a change in the estimated defective die probability exceeds a drift threshold value over time. In some embodiments, the monitored change in the model accuracy may be a change in a distribution of estimated defective die probability. In some embodiments, the monitored change in the model accuracy may be a change in a sample feature contribution to the estimated defective die probability. In some embodiments, the drift threshold value may be a specified deviation in a sample feature contribution over time. In some embodiments, the drift threshold value is evaluated after each CGI model application. In some embodiments, the drift threshold value is evaluated after X CGI model applications, wherein X is an integer. In step 506, after the CGI model is determined to be inaccurate, the CGI model may be retrained as described above. In some embodiments, the CGI model may be retrained by ground truth results. In some embodiments, the ground truth results may be inspection results obtained by an inspection tool. In some embodiments, the ground truth results may be probe test results for a fully processed or fabricated wafer. In some embodiments, a new set of input data for a wafer may be provided to the CGI model for retraining. The new set of input data may be as described above. In some embodiments, a sampling plan generated by a non-CGI model may be used while retraining of the CGI model occurs to minimize disruptions to HVM.

Steps 501-506 are repeated until a sample feature contribution is determined to change over time at a value less than the drift threshold value. This may indicate a CGI model that more accurately predicts die defects or failure of a wafer acquired via wafer processing during HVM. In step 507, if the drift threshold is not exceeded, a sampling plan is generated for in-line inspection. In step 508, the sampling plan is used to guide wafer inspection for the inspection tool.

It is appreciated that method 500 may be performed during HVM and before the “ground truth” results are obtained. After probe test results are obtained for a completed wafer, the probe test results (e.g., actual defective die result) may be compared to the estimated defective die result predicted by the CGI model according to method 500. It is further appreciated that method 500 may occur continuously throughout wafer HVM to ensure the CGI model remains accurate. Inspection results or probe test results for a wafer may be collected to obtain ground truth results periodically or concurrently with method 500 to verify and retrain the CGI model.

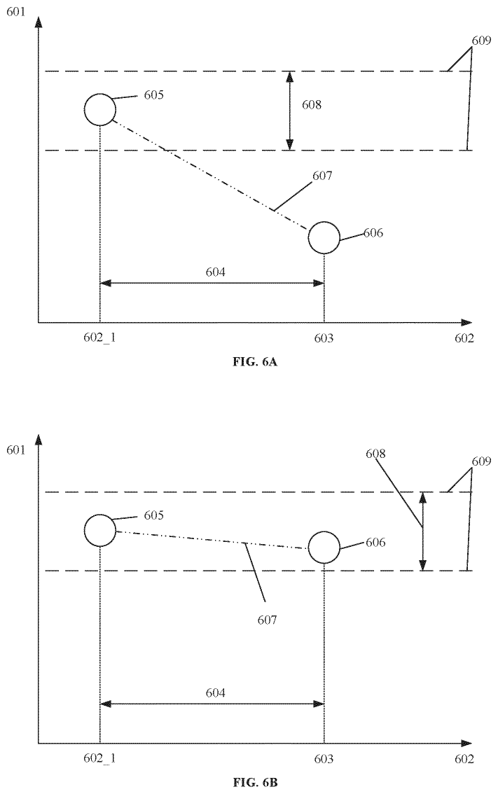

Reference is now made to FIG. 6A, which is an example plot that illustrates monitoring a change in a contribution of a selected sample feature to an estimated defective die probability over time, consistent with embodiments of the present disclosure. FIG. 6A illustrates steps 502 to 505 of method 500 (in FIG. 5). As seen in FIG. 6A, the y-axis represents a sample feature contribution 601 to an estimated defective die probability and the x-ais represents time 602 after a first CGI model application event 602_1. For ease of illustration, first CGI model application event 602_1 is plotted to the right of the (0,0) origin. In some illustrations, first CGI model application event 602_1 may be plotted at the (0,0) origin. A subsequent CGI model application event 603 may correspond to calculating an estimated defective die probability based on input data of a second wafer (e.g., step 503 in FIG. 5). It is appreciated that subsequent CGI model application event 603 may occur later in time compared to the first CGI model application event 602_1. It is further appreciated that subsequent CGI model application event 603 may occur for every X wafer(s), wherein X is an integer. The space 604 between first CGI model application event 602_1 and subsequent CGI model application event 603 may represent a time interval 604 between CGI model application events. Time interval 604 may be a time between a first and a X CGI model application, wherein X is an integer. It is appreciated that FIG. 6A is for illustrative purposes and a greater number of CGI model application events may be represented.

A sample feature contribution 605 corresponding to an estimated defective die probability generated by first CGI model application event 602_1 and a sample feature contribution 606 corresponding to an estimated defective die probability generated by subsequent CGI model application event 603 may be determined as described above in step 505 of method 500 (in FIG. 5). It is appreciated that sample feature contribution 605 and sample feature contribution 606 correspond to the same sample feature. A change 607 from sample feature contribution 605 to sample feature contribution 606 may be represented for ease of illustration as a line 607. An example drift threshold is illustrated as the space 608 within parallel, horizontal lines 609. If a sample feature contribution over time interval 604 remains within drift threshold 608, then the CGI model may be determined to be accurate. As seen in FIG. 6A, over time interval 604, sample feature contribution 605 has decreased to sample feature contribution 606, which is outside of drift threshold 608. This may represent an excursion event and may indicate the CGI model is outdated. The CGI model thus may be retrained as described above and new data may be supplied to the CGI model.

Reference is now made to FIG. 6B, which is an example plot illustrating monitoring a change in a contribution of a selected sample feature to an estimated defective die probability over time, consistent with embodiments of the present disclosure. FIG. 6B may correspond to a contribution of a sample feature in the estimated defective die probability according to steps 502-505 of method 500 (see FIG. 5). As seen in FIG. 6B, a change 607 in the sample feature contribution 605 to the sample feature contribution 606 over time interval 604 is within the boundary of drift threshold 608. The CGI model used to generate the estimated defective die probabilities may be indicated as accurate and stable over time. In some embodiments, the CGI model used to generate the estimate defective die probability with a sample feature as shown in FIG. 6B may be considered accurate for subsequent wafer HVM. Furthermore, a sampling plan or defective die probability map generated by the CGI model may be used to monitor wafer fabrication and maintain a desirable wafer yield.

It is appreciated that FIGS. 6A and 6B are for illustrative purposes, and a greater number of sample features may be monitored over time. In some embodiments, a top N sample features may be monitored, where N is an integer. In some embodiments, sample features may be aggregated to combine the feature attribution drift for all sample features monitored. The aggregation may be performed by, for example, determining a Euclidean distance between feature contribution vectors for a top N sample features. It is further appreciated that the drift threshold range may be smaller or larger than illustrated in FIGS. 6A and 6B. Drift threshold 608 may be determined by the drift values distribution generated from a set of training wafers in a cross-validation fashion. Furthermore, ground truth results comprising inspection results or probe test results at the end of wafer processing may still be obtained to confirm the accuracy of the CGI model after method 500 is performed and used for CGI model retraining, if necessary.

A benefit provided by embodiments of the present disclosure may be an earlier detection of a CGI model change, drift, or degradation of accuracy over time. In some embodiments, the time to detect a CGI model change, drift, or degradation may be significantly reduced. As discussed above, embodiments of the present disclosure may correct CGI model inaccuracies during earlier stages of wafer HVM instead of at the end of processing when probe test results are available for fully fabricated wafers. Embodiments of the present disclosure may provide a more continuous process of monitoring accuracy of a CGI model for wafer HVM and retraining the CGI model to improve model accuracy without ground truth information.

A non-transitory computer readable medium may be provided that may store instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, store instructions for a processor of a lithographic projection apparatus (e.g., lithographic projection apparatus 301 of FIG. 3) and inspection tool (e.g., inspection tool 302 of FIG. 3) to determine input data of a sample, perform method 500 of FIG. 5, and other executable functions relating to estimating defective die probability and monitoring a change in contribution of a feature of the estimated defective die probability over time. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method to detect change in computational model behavior, the method comprising:
monitoring a contribution of a selected sample feature to a defective die probability evaluation over a time interval;
determining whether the contribution of the selected sample feature exceeds a drift threshold in the time interval; and
based on the determination that the drift threshold is exceeded, retraining the computational model.
2. The method of clause 1, wherein monitoring the contribution of the selected sample feature comprises obtaining input data from a scanner or metrology tool and a computational model.
3. The method of clause 2, wherein the input data from the scanner or metrology tool corresponds to metrology information of a first wafer and a second wafer acquired via wafer processing.
4. The method of clause 3, wherein the defective die probability evaluation is an estimated defective die probability based on the input data for the first wafer and the second wafer.
5. The method of any one of clauses 1 to 4, wherein the contribution of the selected sample feature is calculated by a sample feature selection technique.
6. The method of clause 5, wherein the sample feature selection technique is a sum of mean absolute SHAP values.
7. The method of any one of clauses 1 to 6, wherein the time interval is a time between a first and a X computational model application, wherein X is an integer.
8. The method of any one of clauses 3 to 7, wherein retraining the computational model comprises:
applying input data into the computational model for a wafer; and
generating an estimated defective die probability based on the input data for the wafer and input data for the first wafer and the second wafer.
9. The method of clause 8, wherein the input data for the wafer is from a scanner or metrology tool and corresponds to metrology information of the wafer acquired via wafer processing.
10. The method of any one of clauses 3 to 9, wherein the wafer processing comprises a lithographic focus and dose condition.
11. The method of any one of clauses 1 to 10, wherein the computational model is a computational guided inspection model.
12. The method of any one of clauses 1 to 11, wherein the computational model is used by an inspection tool for inspecting a wafer.
13. The method of clause 12, wherein the inspection tool is a scanning electron microscope or an optical tool.
14. The method of clause 12 or 13, wherein a change in the computational model behavior is detected before inspection results are obtained from the inspection tool.
15. The method of any one of clauses 1 to 14, wherein a change in the computational model behavior is detected before a wafer is fully processed.
16. The method of any one of clauses 1 to 15, wherein a change in the computational model behavior is detected before probe test results are obtained for a fully processed wafer.
17. A method of using a computational model to inspect a wafer, the method comprising: inputting data for a first wafer and a second wafer acquired via wafer processing to the computational model;
estimating a defective die probability for the first wafer;
estimating a defective die probability based on input data for the second wafer;
monitoring a change in a contribution of a selected sample feature to the estimated defective die probability for the first wafer and the estimated defective die probability for the second wafer over a time interval;
determining whether the contribution of the selected sample feature exceeds a drift threshold in the time interval and based on the determination that the drift threshold is exceeded, retraining the computational model;
determining whether the contribution of the selected sample feature exceeds a drift threshold in the time interval and based on the determination that the drift threshold is not exceeded, generating a defective die probability map for inspecting a subsequent wafer; and
using the generated defective die probability map to generate a sampling plan to guide wafer inspection.
18. The method of clause 17, wherein the input data comprises metrology information.
19. The method of clause 17 or 18, wherein the wafer processing comprises a lithographic focus and dose condition.
20. The method of any one of clauses 17 to 19, wherein the second wafer is acquired via wafer processing after the first wafer.
21. The method of any one of clauses 17 to 20, wherein the computational model is applied to the second wafer after the computational model is applied to the first wafer.
22. The method of any one of clauses 17 to 21, wherein the contribution of the selected sample feature to the estimated defective die probability is calculated by a feature selection technique.
23. The method of clause 22, wherein the feature selection technique is a sum of mean absolute SHAP values.
24. The method of any one of clauses 17 to 23, wherein the time interval is a time between a first and a X computational model application, wherein X is an integer.
25. The method of any one of clauses 17 to 24, wherein retraining the computational model comprises:
applying input data for a wafer into the computational model; and
generating an estimated defective die probability based on the input data for the wafer and input data for the first wafer and the second wafer.
26. The method of any one of clauses 17 to 25, wherein the computational model is a computational guided inspection model.
27. The method of any one of clauses 17 to 26, wherein the computational model is used by an inspection tool to inspect a wafer.
28. The method of clause 27, wherein the inspection tool is a scanning electron microscope or an optical tool.
29. The method of clause 27 or 28, wherein a change in the computational model behavior is detected before inspection results are obtained from the inspection tool.
30. The method of any one of clauses 17 to 29, wherein a change in the computational model behavior is detected before a wafer is fully processed.
31. The method of any one of clauses 17 to 30, wherein a change in the computational model behavior is detected before probe test results are obtained for a fully processed wafer.
32. An apparatus for detecting a change in computational model behavior, comprising: a memory storing a set of instructions; and
at least one processor configured to execute the set of instructions to cause the apparatus to perform: monitoring a contribution of a selected sample feature to a defective die probability evaluation over a time interval;
determining whether the contribution of the selected sample feature exceeds a drift threshold in the time interval; and based on the determination that the drift threshold is exceeded, retraining the computational model.
33. The apparatus of clause 32, wherein monitoring the contribution of the selected sample feature comprises obtaining input data from a scanner or metrology tool and a computational model.
34. The apparatus of clause 33, wherein the input data from the scanner or metrology tool corresponds to metrology information of a first wafer and a second wafer acquired via wafer processing.
35. The apparatus of clause 34, wherein the defective die probability evaluation is an estimated defective die probability based on the input data for the first wafer and the second wafer.
36. The apparatus of any one of clauses 32 to 35, wherein the contribution of the selected sample feature is calculated by a sample feature selection technique.
37. The apparatus of clause 36, wherein the sample feature selection technique is a sum of mean absolute SHAP values.
38. The apparatus of any one of clauses 32 to 37, wherein the time interval is a time between a first and a X computational model application, wherein X is an integer.
39. The apparatus of any one of clauses 32 to 38, wherein retraining the computational model comprises:
applying input data into the computational model for a wafer; and
generating an estimated defective die probability based on the input data for the wafer and input data for the first wafer and the second wafer.
40. The apparatus of clause 39, wherein the input data for the wafer is from a scanner or metrology tool and corresponds to metrology information of the wafer acquired via wafer processing.
41. The apparatus of any one of clauses 34 to 40, wherein the wafer processing comprises a lithographic focus and dose condition.
42. The apparatus of any one of clauses 32 to 41, wherein the computational model is a computational guided inspection model.
43. The apparatus of any one of clauses 32 to 42, wherein the computational model is used by an inspection tool for inspecting a wafer.
44. The apparatus of clause 43, wherein the inspection tool is a scanning electron microscope or an optical tool.
45. The apparatus of clause 43 or 44, wherein a change in the computational model behavior is detected before inspection results are obtained from the inspection tool.
46. The apparatus of any one of clauses 32 to 45, wherein a change in the computational model behavior is detected before a wafer is fully processed.
47. The apparatus of any one of clauses 32 to 46, wherein a change in the computational model behavior is detected before probe test results are obtained for a fully processed wafer.
48. An apparatus for using a computational model to inspect a wafer, comprising:
a memory storing a set of instructions; and
at least one processor configured to execute the set of instructions to cause the apparatus to perform: inputting data for a first wafer and a second wafer acquired via wafer processing to the computational model;
estimating a defective die probability for the first wafer;
estimating a defective die probability based on input data for the second wafer;
monitoring a change in a contribution of a selected sample feature to the estimated defective die probability for the first wafer and the estimated defective die probability for the second wafer over a time interval;
determining whether the contribution of the selected sample feature exceeds a drift threshold in the time interval and based on the determination that the drift threshold is exceeded, retraining the computational model;
determining whether the contribution of the selected sample feature exceeds a drift threshold in the time interval and based on the determination that the drift threshold is not exceeded, generating a defective die probability map for inspecting a subsequent wafer; and
using the generated defective die probability map to generate a sampling plan to guide wafer inspection.
49. The apparatus of clause 48, wherein the input data comprises metrology information.
50. The apparatus of clause 48 or 49, wherein the wafer processing comprises a lithographic focus and dose condition.
51. The apparatus of any one of clauses 48 to 50, wherein the second wafer is acquired via wafer processing after the first wafer.
52. The apparatus of any one of clauses 48 to 51, wherein the computational model is applied to the second wafer after the computational model is applied to the first wafer.
53. The apparatus of any one of clauses 48 to 52, wherein the contribution of the selected sample feature to the estimated defective die probability is calculated by a feature selection technique.
54. The apparatus of clause 53, wherein the feature selection technique is a sum of mean absolute SHAP values.
55. The apparatus of any one of clauses 48 to 54, wherein the time interval is a time between a first and a X computational model application, wherein X is an integer.
56. The apparatus of any one of clauses 48 to 55, wherein retraining the computational model comprises:
applying input data for a wafer into the computational model; and
generating an estimated defective die probability based on the input data for the wafer and input data for the first wafer and the second wafer.
57. The apparatus of any one of clauses 48 to 56, wherein the computational model is a computational guided inspection model.
58. The apparatus of any one of clauses 48 to 57, wherein the computational model is used by an inspection tool to inspect a wafer.
59. The apparatus of clause 58, wherein the inspection tool is a scanning electron microscope or an optical tool.
60. The apparatus of clause 58 or 59, wherein a change in the computational model behavior is detected before inspection results are obtained from the inspection tool.
61. The apparatus of any one of clauses 48 to 60, wherein a change in the computational model behavior is detected before a wafer is fully processed.
62. The apparatus of any one of clauses 48 to 61, wherein a change in the computational model behavior is detected before probe test results are obtained for a fully processed wafer.
63. A non-transitory computer readable medium comprising a set of instructions that is executable by one or more processors of a computing device to cause the computing device to perform operations for detecting a change in computational model behavior, the operations comprising:
monitoring a contribution of a selected sample feature to a defective die probability evaluation over a time interval;
determining whether the contribution of the selected sample feature exceeds a drift threshold in the time interval; and
based on the determination that the drift threshold is exceeded, retraining the computational model.
64. The non-transitory computer readable medium of clause 63, wherein monitoring the contribution of the selected sample feature comprises obtaining input data from a scanner or metrology tool and a computational model.
65. The non-transitory computer readable medium of clause 64, wherein the input data from the scanner or metrology tool corresponds to metrology information of a first wafer and a second wafer acquired via wafer processing.
66. The non-transitory computer readable medium of clause 65, wherein the defective die probability evaluation is a defective die probability based on the input data for the first wafer and the second wafer.
67. The non-transitory computer readable medium of any one of clauses 63 to 66, wherein the contribution of the selected sample feature is calculated by a sample feature selection technique.
68. The non-transitory computer readable medium of clause 67, wherein the sample feature selection technique is a sum of mean absolute SHAP values.
69. The non-transitory computer readable medium of any one of clauses 63 to 66, wherein the time interval is a time between a first and a X computational model application, wherein X is an integer.
70. The non-transitory computer readable medium of any one of clauses 63 to 69, wherein retraining the computational model comprises:
applying input data into the computational model for a wafer; and
generating an estimated defective die probability based on the input data for the wafer and input data for the first wafer and the second wafer.
71. The non-transitory computer readable medium of clause 70, wherein the input data for the wafer is from a scanner or metrology tool and corresponds to metrology information of the wafer acquired via wafer processing.
72. The non-transitory computer readable medium of any one of clauses 65 to 71, wherein the wafer processing comprises a lithographic focus and dose condition.
73. The non-transitory computer readable medium of any one of clauses 63 to 72, wherein the computational model is a computational guided inspection model.
74. The non-transitory computer readable medium of any one of clauses 63 to 73, wherein the computational model is used by an inspection tool for inspecting a wafer.
75. The non-transitory computer readable medium of clause 74, wherein the inspection tool is a scanning electron microscope or an optical tool.
76. The non-transitory computer readable medium of clause 74 or 75, wherein a change in the computational model behavior is detected before inspection results are obtained from the inspection tool.
77. The non-transitory computer readable medium of any one of clauses 63 to 76, wherein a change in the computational model behavior is detected before a wafer is fully processed.
78. The non-transitory computer readable medium of any one of clauses 63 to 77, wherein a change in the computational model behavior is detected before probe test results are obtained for a fully processed wafer.
79. A non-transitory computer readable medium comprising a set of instructions that is executable by one or more processors of a computing device to cause the computing device to perform operations for using a computational model to inspect a wafer, the operations comprising:
inputting data for a first wafer and a second wafer acquired via wafer processing to the computational model;
estimating a defective die probability for the first wafer;
estimating a defective die probability based on input data for the second wafer;
monitoring a change in a contribution of a selected sample feature to the estimated defective die probability for the first wafer and the estimated defective die probability for the second wafer over a time interval;
determining whether the contribution of the selected sample feature exceeds a drift threshold in the time interval and based on the determination that the drift threshold is exceeded, retraining the computational model;
determining whether the contribution of the selected sample feature exceeds a drift threshold in the time interval and based on the determination that the drift threshold is not exceeded, generating a defective die probability map for inspecting a subsequent wafer; and
using the generated defective die probability map to generate a sampling plan to guide wafer inspection.
80. The non-transitory computer readable medium of clause 79, wherein the input data comprises metrology information.
81. The non-transitory computer readable medium of clause 79 or 80, wherein the wafer processing comprises a lithographic focus and dose condition.
82. The non-transitory computer readable medium of any one of clauses 79 to 81, wherein the second wafer is acquired via wafer processing after the first wafer.
83. The non-transitory computer readable medium of any one of clauses 79 to 82, wherein the computational model is applied to the second wafer after the computational model is applied to the first wafer.
84. The non-transitory computer readable medium of any one of clauses 79 to 83, wherein the contribution of the selected sample feature to the estimated defective die probability is calculated by a feature selection technique.
85. The non-transitory computer readable medium of clause 84, wherein the feature selection technique is a sum of mean absolute SHAP values.
86. The non-transitory computer readable medium of any one of clauses 79 to 85, wherein the time interval is a time between a first and a X computational model application, wherein X is an integer.
87. The non-transitory computer readable medium of any one of clauses 79 to 86, wherein retraining the computational model comprises:
applying input data for a wafer into the computational model; and
generating an estimated defective die probability based on the input data for the wafer and input data for the first wafer and the second wafer.
88. The non-transitory computer readable medium of any one of clauses 79 to 87, wherein the computational model is a computational guided inspection model.
89. The non-transitory computer readable medium of any one of clauses 79 to 88, wherein the computational model is used by an inspection tool to inspect a wafer.
90. The non-transitory computer readable medium of clause 89, wherein the inspection tool is a scanning electron microscope or an optical tool.
91. The non-transitory computer readable medium of clause 89 or 90, wherein a change in the computational model behavior is detected before inspection results are obtained from the inspection tool.
92. The non-transitory computer readable medium of any one of clauses 79 to 91, wherein a change in the computational model behavior is detected before a wafer is fully processed.
93. The non-transitory computer readable medium of any one of clauses 79 to 92, wherein a change in the computational model behavior is detected before probe test results are obtained for a fully processed wafer.
94. An inspection system using a computational model to inspect a wafer, the inspection system comprising:
one or more processors configured to execute instructions to cause the inspection system to perform: inputting data for a first wafer and a second wafer acquired via wafer processing to the computational model;
estimating a defective die probability for the first wafer;
estimating a defective die probability based on input data for the second wafer;
monitoring a change in a contribution of a selected sample feature to the estimated defective die probability for the first wafer and the estimated defective die probability for the second wafer over a time interval;
determining whether the contribution of the selected sample feature exceeds a drift threshold in the time interval and based on the determination that the drift threshold is exceeded, retraining the computational model;
determining whether the contribution of the selected sample feature exceeds a drift threshold in the time interval and based on the determination that the drift threshold is not exceeded, generating a defective die probability map for inspecting a subsequent wafer; and
using the generated defective die probability map to generate a sampling plan to guide wafer inspection.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, and other embodiments will be apparent to those skilled in the art from consideration of the specification and practice of the technology disclosed herein. It is intended that the specification and examples be considered as exemplary only, with a true scope and spirit of the disclosure being indicated by the following claims.

1. An apparatus for detecting a change in computational model behavior, comprising:
a memory storing a set of instructions; and
at least one processor configured to execute the set of instructions to cause the apparatus to perform:
monitoring a contribution of a selected sample feature to a defective die probability evaluation over a time interval;
determining whether the contribution of the selected sample feature exceeds a drift threshold in the time interval; and
based on the determination that the drift threshold is exceeded, retraining the computational model.

2. The apparatus of claim 1, wherein monitoring the contribution of the selected sample feature comprises obtaining input data from a scanner or metrology tool and a computational model.

3. The apparatus of claim 2, wherein the input data from the scanner or metrology tool corresponds to metrology information of a first wafer and a second wafer acquired via wafer processing.

4. The apparatus of claim 3, wherein the defective die probability evaluation is an estimated defective die probability based on the input data for the first wafer and the second wafer.

5. The apparatus of claim 1, wherein the contribution of the selected sample feature is calculated by a sample feature selection technique.

6. The apparatus of claim 5, wherein the sample feature selection technique is a sum of mean absolute SHAP values.

7. The apparatus of claim 1, wherein the time interval is a time between a first and a X computational model application, wherein X is an integer.

8. The apparatus of claim 1, wherein retraining the computational model comprises:
applying input data into the computational model for a wafer; and
generating an estimated defective die probability based on the input data for the wafer and input data for a first wafer and a second wafer.

9. The apparatus of claim 8, wherein the input data for the wafer is from a scanner or metrology tool and corresponds to metrology information of the wafer acquired via wafer processing.

10. The apparatus of claim 3, wherein the wafer processing comprises a lithographic focus and dose condition.

11. The apparatus of claim 1, wherein the computational model is a computational guided inspection model.

12. The apparatus of claim 1, wherein the computational model is used by an inspection tool for inspecting a wafer.

13. The apparatus of claim 12, wherein the inspection tool is a scanning electron microscope or an optical tool.

14. The apparatus of claim 12, wherein a change in the computational model behavior is detected before inspection results are obtained from the inspection tool.

15. The apparatus of claim 1, wherein a change in the computational model behavior is detected before a wafer is fully processed.

16. A non-transitory computer readable medium comprising a set of instructions that is executable by one or more processors of a computing device to cause the computing device to perform operations for detecting a change in computational model behavior, the operations comprising:
monitoring a contribution of a selected sample feature to a defective die probability evaluation over a time interval;
determining whether the contribution of the selected sample feature exceeds a drift threshold in the time interval; and
based on the determination that the drift threshold is exceeded, retraining the computational model.

17. The non-transitory computer readable medium of claim 16, wherein monitoring the contribution of the selected sample feature comprises obtaining input data from a scanner or metrology tool and a computational model.

18. The non-transitory computer readable medium of claim 17, wherein the input data from the scanner or metrology tool corresponds to metrology information of a first wafer and a second wafer acquired via wafer processing.

19. The non-transitory computer readable medium of claim 18, wherein the defective die probability evaluation is a defective die probability based on the input data for the first wafer and the second wafer.

20. A method to detect change in computational model behavior, the method comprising:
monitoring a contribution of a selected sample feature to a defective die probability evaluation over a time interval;
determining whether the contribution of the selected sample feature exceeds a drift threshold in the time interval; and
based on the determination that the drift threshold is exceeded, retraining the computational model.
